(19) United States
(12) Patent Application Publication
(10) Pub. No.: US 2023/0028286 A1
(43) Pub. Date: Jan. 26, 2023

(54) SENSOR ELEMENT AND SENSOR SYSTEM

(71) Applicants: Masami TAKAI, Tokyo (JP); Kazuhito KISHI, Kanagawa (JP); Mizuki OTAGIRI, Kanagawa (JP); Atsushi OHSHIMA, Osaka (JP); Takahiro IMAI, Tokyo (JP); Junichiro NATORI, Kanagawa (JP); Tsuneaki KONDOH, Kanagawa (JP); Tomoaki SUGAWARA, Kanagawa (JP)

(72) Inventors: Masami TAKAI, Tokyo (JP); Kazuhito KISHI, Kanagawa (JP); Mizuki OTAGIRI, Kanagawa (JP); Atsushi OHSHIMA, Osaka (JP); Takahiro IMAI, Tokyo (JP); Junichiro NATORI, Kanagawa (JP); Tsuneaki KONDOH, Kanagawa (JP); Tomoaki SUGAWARA, Kanagawa (JP)

(73) Assignee: Ricoh Company, Ltd., Tokyo (JP)

(21) Appl. No.: 17/758,478

(22) PCT Filed: Jan. 20, 2021
(86) PCT No.: PCT/JP2021/001895

§ 371 Date: Jul. 7, 2022

(30) Foreign Application Priority Data
Jan. 24, 2020 (JP) 2020-010355
Jan. 28, 2020 (JP) 2020-011863
Nov. 30, 2020 (JP) 2020-199114

(51) Int. Cl. G01L 1/16

(52) U.S. Cl. CPC G01L 1/16

(57) ABSTRACT

(Object) To reduce the power consumption. (Means of Achieving the object) A sensor element according to an aspect of the present invention is used in a sensor system, the sensor system including at least one of a detector and a calculator, and a power source, the sensor element including a charge generation element configured to generate a charge in response to an external stimulus; and a signal converter configured to convert the charge into a predetermined output signal, wherein the signal converter is formed of one or more passive elements only, and an initial driving power for the signal converter is supplied from the power source.

### TECHNICAL FIELD

The present invention relates to a sensor element and a sensor system.

### BACKGROUND ART

Conventionally, sensor elements such as pressure sensors and acceleration sensors that use piezoelectric elements, which generate charges according to physical deformation amounts, are known.

There is also disclosed a sensor element including an integrator circuit for integrating the output of the piezoelectric element, an amplifier circuit for amplifying the output of the integrator circuit, and a reference voltage source for defining the offset voltage of the amplifier circuit (see, e.g., Patent Literature 1).

### CITATION LIST

### Patent Literature

PTL 1: Japanese Patent No. 6538532

### SUMMARY OF INVENTION

### Technical Problem

However, the sensor element of Patent Literature 1 includes a signal conversion circuit that converts a signal, which is obtained by a charge generation element such as a piezoelectric element, into a predetermined output signal, by using an active element that consumes power, and, therefore, there is margin for improvement because the power consumption is large.

The disclosed technology is thus intended to reduce the power consumption of the sensor element.

### Solution to Problem

According to an aspect of the present invention, a sensor element is used in a sensor system, the sensor system including at least one of a detector and a calculator, and a power source, the sensor element including a charge generation element configured to generate a charge in response to an external stimulus; and a signal converter configured to convert the charge into a predetermined output signal, wherein the signal converter is formed of one or more passive elements only, and an initial driving power for the signal converter is supplied from the power source.

### Effects of Invention

According to the present invention, power consumption of the sensor element can be reduced.

### BRIEF DESCRIPTION OF DRAWINGS

FIG. 1 is a block diagram illustrating an example of a configuration of a sensor system according to a first embodiment of the present invention.

FIG. 2A is a diagram illustrating an example of a configuration of a first example of a signal conversion circuit according to a first embodiment of the present invention.

FIG. 2B is a graph illustrating an example of an output signal of a first example of a signal conversion circuit according to a first embodiment of the present invention.

FIG. 3A is a diagram illustrating an example of a configuration of a second example of a signal conversion circuit according to a first embodiment of the present invention.

FIG. 3B is a graph illustrating an example of an output signal of a second example of a signal conversion circuit according to a first embodiment of the present invention.

FIG. 4A is a diagram illustrating an example of a configuration of a third example of a signal conversion circuit according to a first embodiment of the present invention.

FIG. 4B is a graph illustrating an example of an output signal of a third example of a signal conversion circuit according to a first embodiment of the present invention.

FIG. 5A is a diagram illustrating an example of a configuration of a fourth example of a signal conversion circuit according to a first embodiment of the present invention.

FIG. 5B is a graph illustrating an example of an output signal of a fourth example of a signal conversion circuit according to a first embodiment of the present invention.

FIG. 6A is a graph illustrating an example of a detection method using voltage value sampling by a detecting unit according to a first embodiment of the present invention.

FIG. 6B is a graph illustrating an example of a detection method using a threshold voltage by a detecting unit according to a first embodiment of the present invention.

FIG. 6C is a graph illustrating an example of a detection method using peak-hold by a detecting unit according to a first embodiment of the present invention.

FIG. 6D is a graph illustrating an example of a detection method using a threshold differential voltage by a detecting unit according to a first embodiment of the present invention.

FIG. 7 is a diagram illustrating the configuration of a signal conversion unit according to a comparative example.

FIG. 8 is a graph illustrating an output signal according to a comparative example.

FIG. 9 is a block diagram illustrating an example of a configuration of a sensor system according to a second embodiment of the present invention.

FIG. 10 is a block diagram illustrating another example of a configuration of a sensor system according to a second embodiment of the present invention.

FIG. 11 is a block diagram illustrating an example of a configuration of a sensor system according to a third embodiment of the present invention.

FIG. 12 is a graph illustrating an example of voltage output characteristics of a secondary battery according to a third embodiment of the present invention.

FIG. 13 is a diagram illustrating an overall configuration example of an insole according to a fourth embodiment of the present invention.

FIG. 14 is a block diagram illustrating an example of a configuration of a processing unit according to a fourth embodiment of the present invention.

FIG. 15A is a graph illustrating an example of output data of a processing unit in a case in which an insole user steps on the spot according to a fourth embodiment of the present invention.

FIG. 15B is a graph illustrating an example of output data of a processing unit in a case in which an insole user advances one step forward according to a fourth embodiment of the present invention.

FIG. 16 is a diagram illustrating an example of an overall configuration of footwear according to a fifth embodiment of the present invention.

FIG. 17A is a diagram illustrating a detection example by a pressure type passage sensor according to a sixth embodiment of the present invention.

FIG. 17B is a diagram illustrating a detection example by a pressure type passage sensor according to a sixth embodiment of the present invention.

FIG. 17C is a diagram illustrating a detection example by a pressure type passage sensor according to a sixth embodiment of the present invention.

FIG. 18 is a diagram illustrating a detection example by the contact state sensor according to a seventh embodiment of the present invention.

FIG. 19 is a diagram illustrating a detection example using a bending/stretching sensor according to an eighth embodiment of the present invention.

FIG. 20 is a diagram illustrating a detection example by a deformation passage sensor according to a ninth embodiment of the present invention.

### DESCRIPTION OF EMBODIMENTS

Hereinafter, an embodiment for carrying out the present invention will be described with reference to the drawings. In the following drawings, the same elements are denoted by the same reference numerals, and overlapping descriptions are omitted accordingly.

A sensor element according to an embodiment is used in a sensor system including at least one of a detecting unit and a calculating unit, and a power source. The sensor element includes a charge generation element that generates a charge in response to an external stimulus and a signal converter that converts the charge generated by the charge generation element into a predetermined output signal.

In an embodiment, the signal converter is formed of only a passive element, and an initial driving power for the signal converter is provided from a power source in the sensor system. By configuring the signal converter with only a passive element, the power consumption of the signal converter is reduced, and the power consumption of the sensor element is reduced.

In first to third embodiments, an example of a sensor system including a sensor element according to an embodiment will be described. In a fourth embodiment, an example of an insole including the sensor element will be described. In a fifth embodiment, an example of footwear including the sensor element will be described.

### First Embodiment

<Example of Configuration of Sensor System>

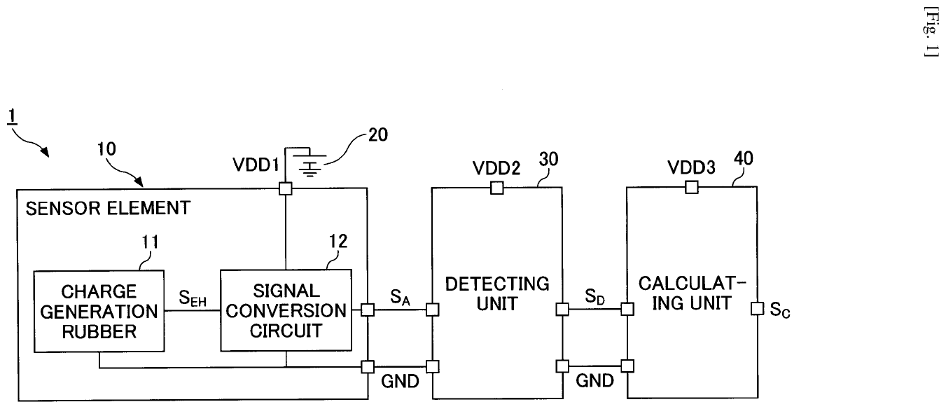

First, a sensor system 1 according to the first embodiment will be described with reference to FIG. 1. FIG. 1 is a block diagram illustrating an example of a configuration of the sensor system 1.

As illustrated in FIG. 1, the sensor system 1 includes a sensor element 10, a power source 20, a detecting unit 30 (an example of a detector), and a calculating unit 40 (an example of a calculator).

Among these, the sensor element 10 includes a charge generation rubber 11 and a signal conversion circuit 12. The sensor element 10 is an element (device) that converts the charge generated according to external stimuli such as pressure, into a predetermined output signal S_{A} and outputs the output signal S_{A}. The output signal S_{A} corresponds to a detection signal of the detected pressure, etc., by the sensor element 10.

The charge generation rubber 11 is a power generation rubber that generates an electric charge by deforming in response to an external stimulus such as pressure. The charge generation rubber 11 is an example of a charge generation element that generates a charge derived from an external force. However, the charge generation element is not limited to the charge generation rubber 11, and may be another element, such as a piezoelectric element, an electret, and the like, as long as it is possible to generate an electric charge derived from an external force. However, the output impedance of these charge generation elements is high, and, therefore, it is possible that the maximum voltage value of the voltage waveform of the output power becomes greater than or equal to the maximum value of the dynamic range (effective voltage range). Examples of external forces include physical energy such as peel forces, friction forces, vibration forces, deformation forces, as well as light energy and thermal energy.

A signal S_{EH} according to the charge generated by the charge generation rubber 11, is input to the signal conversion circuit 12.

The signal conversion circuit 12 is an electrical circuit that receives a signal S_{EH} from the charge generation rubber 11, converts the signal S_{EH} into an output signal S_{A} having a predetermined offset voltage and a dynamic range (effective voltage range), and outputs the output signal S_{A} to the detecting unit 30. The signal conversion circuit 12 can also function as an impedance matching circuit that converts the impedance of the output signal S_{A} so that the output signal S_{A} can be input to the detecting unit 30.

The signal conversion circuit 12 is formed of only a passive element and is driven by a voltage VDD1 supplied from the power source 20. That is, the signal conversion circuit 12 receives an initial driving power supplied from the power source 20.

The power source 20 is a power source for supplying power to the signal conversion circuit 12. The power source 20 may be configured by a primary battery, a secondary battery, a capacitor, and the like. As an example, the power source 20 applies a voltage of 3.6 V to the signal conversion circuit 12 to supply power. In this case, the signal conversion circuit 12 generates a signal with an offset voltage of 1.8 V and a dynamic range of 0 V to 3.6 V based on the signal S_{EH} input from the charge generation rubber 11.

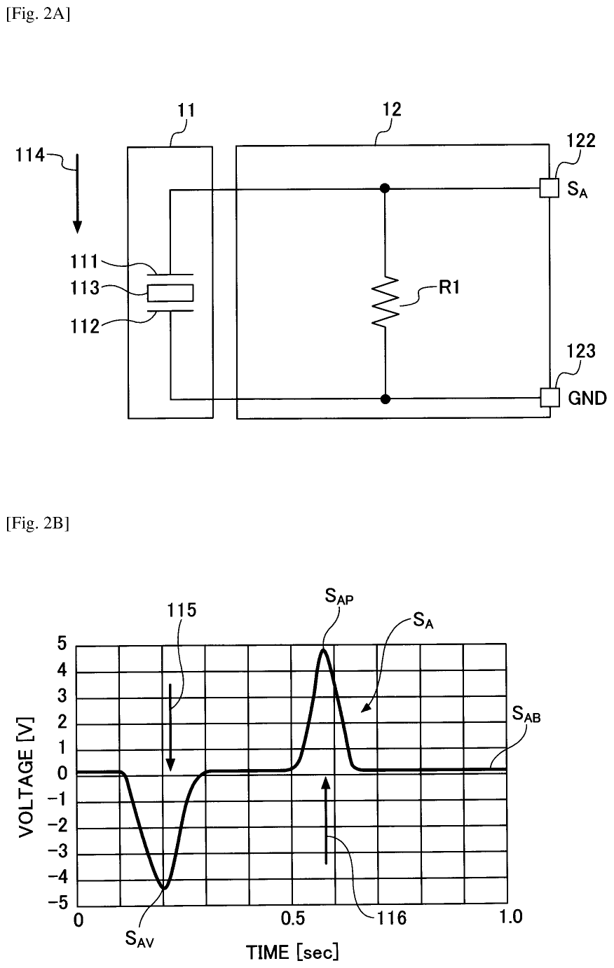

The signal conversion circuit 12 may set the offset voltage of the generated signal to be a reference voltage of 0 V to 3.6 V, convert the generated signal to the output signal S_{A} so that the dynamic range is 0 V to 3.6 V, and output the output signal S_{A} to the detecting unit 30. The specific configuration of the signal conversion circuit 12 is described below with reference to FIGS. 2A to 5B. Here, the signal conversion circuit 12 is an example of a signal converter.

The detecting unit 30 is an electrical circuit that detects the output signal S_{A}, which is an analog signal input from the signal conversion circuit 12, by Analog/Digital (A/D) conversion, and outputs the detected digital signal S_{D} to the calculating unit 40. The detecting unit 30 is driven by a voltage VDD2 supplied from any power source. The voltage VDD2 is preferably greater than or equal to the voltage VDD1.

The calculating unit 40 is configured by a central processing unit (CPU) and the like, and is a processor that performs an analysis process on the digital signal S_{D} input from the detecting unit 30, and outputs analysis data S_{C}. The calculating unit 40 is driven by a voltage VDD3 supplied from an any power source. The voltage VDD3 can adjust the digital signal S_{D} to a voltage that can be input to the calculating unit 40, and, therefore the voltage VDD3 may be set to any voltage value.

Each of the detecting unit 30 and the calculating unit 40 may be implemented by using an external apparatus such as a personal computer (PC). Further, the sensor system 1 can be configured such that the calculating unit 40 includes a function of the detecting unit 30, and the detecting unit 30 includes a function of the calculating unit 40.

<Example of Configuration of the Signal Conversion Circuit 12>

Next, the configuration of the signal conversion circuit 12 will be described. Various configurations and arrangements using various passive elements that do not consume power can be applied to the signal conversion circuit 12, and, therefore, four examples of configurations will be described below with reference to FIGS. 2A to 5B.

### First Configuration Example

FIGS. 2A and 2B are diagrams illustrating a first example of a signal conversion circuit, wherein FIG. 2A is a diagram illustrating an example of the configuration, and FIG. 2B is a graph illustrating an example of an output signal.

Note that FIG. 2B illustrates an output signal when an external stimulus is applied to the charge generation rubber 11. More specifically, FIG. 2B illustrates an output signal in a case where a user using the sensor system (hereinafter referred to as the user) steps on the charge generation rubber 11 with his or her foot to apply an external stimulus to the charge generation rubber 11, in which the user steps on the charge generation rubber 11 once to apply pressure to the charge generation rubber 11, and subsequently, the user releases his or her foot from the charge generation rubber 11 to reduce the pressure. When the user repeatedly performs the action of stepping on the charge generation rubber 11, the output signal illustrated in FIG. 2B is repeatedly obtained according to the number of times the action is performed. These points are similarly applicable to the other figures illustrating the output signal described below.

As illustrated in FIG. 2A, the signal conversion circuit 12 includes a resistor R1, an output terminal 122, and a GND terminal 123.

The resistor R1 is coupled in parallel to the charge generation rubber 11. One end of the resistor R1 is coupled to the output terminal 122 and the other end is coupled to the GND terminal 123. When the current (charge) output by the charge generation rubber 11 flows to the resistor R1, a voltage, which uses the GND voltage coupled to one end of the resistor R1 as a reference, is generated along the direction of the current (charge) flow.

The output voltage of the signal conversion circuit 12 illustrated in FIG. 2A becomes a positive voltage and a negative voltage relative to the GND potential, and, therefore, the power source of the detecting unit 30 needs to be configured to be driven by a t power source.

The output terminal 122 outputs an output signal S_{A} converted by the signal conversion circuit 12. The GND terminal 123 is the ground terminal which is the reference of the potential.

The charge generation rubber 11 includes a first electrode 111, a second electrode 112, and an intermediate layer 113. The intermediate layer 113 is a flexible layer formed of rubber or a rubber composition. The first electrode 111 and the second electrode 112 are stacked so as to sandwich the intermediate layer 113 to form the charge generation rubber 11.

The relationship between the charge and the current in the signal S_{EH} generated by deformation of the charge generation rubber 11 in response to an external stimulus, is expressed by a formula (1) below.

I_{EH}=Q_{EH}/t (1)

Here, in formula (1), I_{EH} represents the current, Q_{EH} represents the charge, and t represents the time.

The current I_{EH} flows in the direction indicated by an arrow 114 of FIG. 2A, and the output terminal 122 outputs an output signal S_{A} which is a voltage signal using the GND voltage as a reference. The direction opposite to the arrow 114 corresponds to the direction in which the charge Q_{EH} changes.

As illustrated in FIG. 2B, the output signal S_{A} is a signal having the GND voltage (0 V) as a reference voltage S_{AB}, and includes a peak voltage S_{AV} in the negative direction and a peak voltage S_{AP} in the positive direction. In an embodiment, the signal conversion circuit 12 acquires a signal having a peak in both the positive direction and the negative direction, so that the direction in which an external stimulus is applied to the charge generation rubber 11 can be detected.

More specifically, when the user steps on the charge generation rubber 11 with his or her foot to apply an external stimulus to the charge generation rubber 11, a peak voltage S_{AV} in the negative direction is obtained when the charge generation rubber 11 is stepped on by the foot, and a peak voltage S_{AP} in the positive direction is obtained when the foot is separated from the charge generation rubber 11. By such an output signal S_{A}, it is possible to acquire information on the direction and magnitude of the external stimulus applied to the charge generation rubber 11.

Here, the peak voltage S_{AP} in the positive direction is an example of an extreme value in the positive direction and the peak voltage S_{AV} in the negative direction is an example of an extreme value in the negative direction.

In FIG. 2B, an arrow 115 indicates the direction in which the current flows at the time of the peak voltage S_{AV} in the negative direction, and an arrow 116 indicates the direction in which current flows at the time of the peak voltage S_{AP} in the positive direction.

### Second Configuration Example

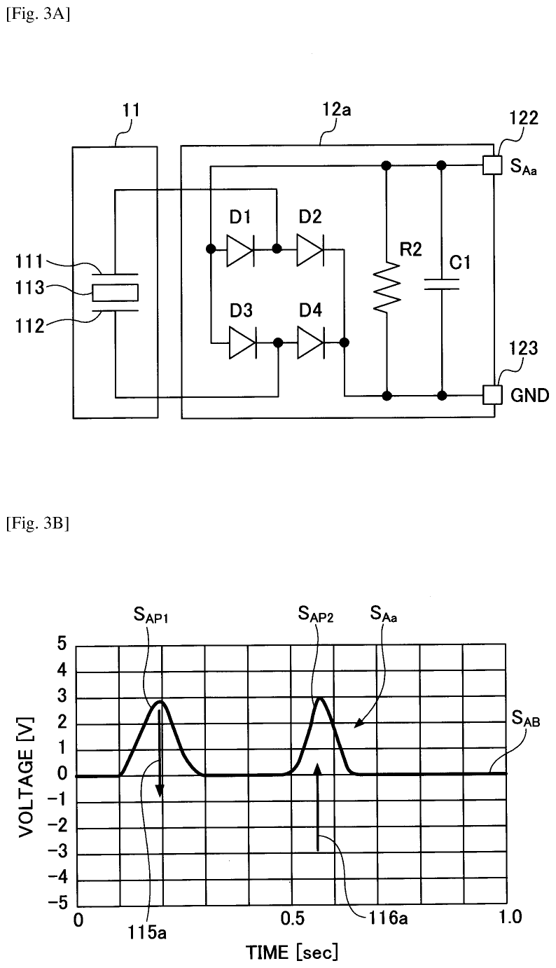

Next, FIGS. 3A and 3B are diagrams illustrating a second example of a signal conversion circuit, wherein FIG. 3A is a diagram illustrating an example of the configuration, and FIG. 3B is a graph illustrating an example of an output signal.

As illustrated in FIG. 3A, a signal conversion circuit 12a includes diodes D1 to D4, a resistor R2, and a capacitor C1.

The diodes D1 to D4 are arranged in bridges to form a full-wave rectifier circuit, and rectify the negative voltage portion of the input voltage to the signal conversion circuit 12a to generate a positive voltage.

The resistor R2 and the capacitor C1 are coupled, in parallel with each other, to the charge generation rubber 11; one end of each being coupled to the output terminal 122 and the other end being coupled to the GND terminal 123. The resistor R2 and the capacitor C1 perform noise processing and waveform shaping on the direct current (DC) voltage after full-wave rectification by the diodes D1 to D4, to generate an output signal S_{Aa}.

As illustrated in FIG. 3B, the output signal S_{Aa} is a signal having the GND voltage as the reference voltage S_{AB}, and includes a first peak voltage S_{AP1} in the positive direction and a second peak voltage S_{AP2} in the positive direction. The full-wave rectifier circuit converts/rectifies the negative voltage portion to a positive voltage, thereby obtaining two peak voltages in the positive direction.

In FIG. 3B, an arrow 115a indicates the direction in which the current flows at the time of the first peak voltage S_{AP1}, and an arrow 116a indicates the direction in which the current flows at the time of the second peak voltage Sm.

As described above, by configuring the signal conversion circuit 12a to include the full-wave rectifier circuit, it is possible to reduce noise and adjust the output voltage level (dynamic range), and the like.

### Third Configuration Example

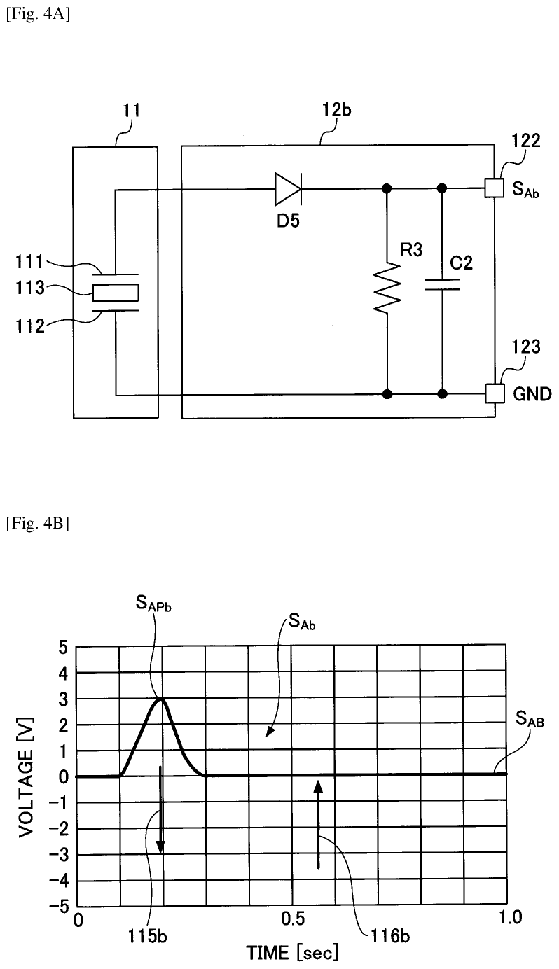

Next, FIGS. 4A and 4B are diagrams illustrating a third example of a signal conversion circuit, wherein FIG. 4A is a diagram illustrating an example of the configuration, and FIG. 4B is a graph illustrating an example of an output signal.

As illustrated in FIG. 4A, a signal conversion circuit 12b includes a diode D5, a resistor R3, and a capacitor C2.

The diode D5 is coupled in series with the charge generation rubber 11 to form a half-wave rectifier circuit. The diode D5 performs rectification by passing only one of the currents flowing in both a positive direction and a negative direction, among the alternating currents input from the charge generation rubber 11.

The resistor R3 and the capacitor C2 are coupled to the charge generation rubber 11; one end of each being coupled to the output terminal 122 and the other end being coupled to the GND terminal 123. The resistor R3 and the capacitor C2 perform noise processing and waveform shaping on the direct current (DC) voltage after half-wave rectification by the diode D5, to generate an output signal S_{Ab}.

As illustrated in FIG. 4B, the output signal S_{Ab} is a signal having the GND voltage as the reference voltage S_{AB}, and includes a peak voltage S_{APb} in the positive direction. The function of the half-wave rectifier circuit allows only the flow of the positive direction portion of the current flowing in both the positive and negative directions, thus obtaining only the peak voltage S_{APb} in the positive direction.

In FIG. 4B, an arrow 115b indicates the direction in which the current flows at the time of the peak voltage S_{APb}, and an arrow 116a indicates the direction in which the current flows when the peak voltage is obtained by the output signal S_{A} before half-wave rectification.

By configuring the signal conversion circuit 12b to include the half-wave rectifier circuit in this manner, the signal conversion circuit can be configured with a small number of components.

By using the half-wave rectifier circuit, it is possible to obtain the peak voltage S_{APb} in the positive direction only when the charge generation rubber 11 is stepped on by the foot, or to obtain the peak voltage S_{APb} in the positive direction only when the foot is separated from the charge generation rubber 11, thereby obtaining information on the direction and magnitude of the external stimulus applied to the charge generation rubber 11.

### Fourth Configuration Example

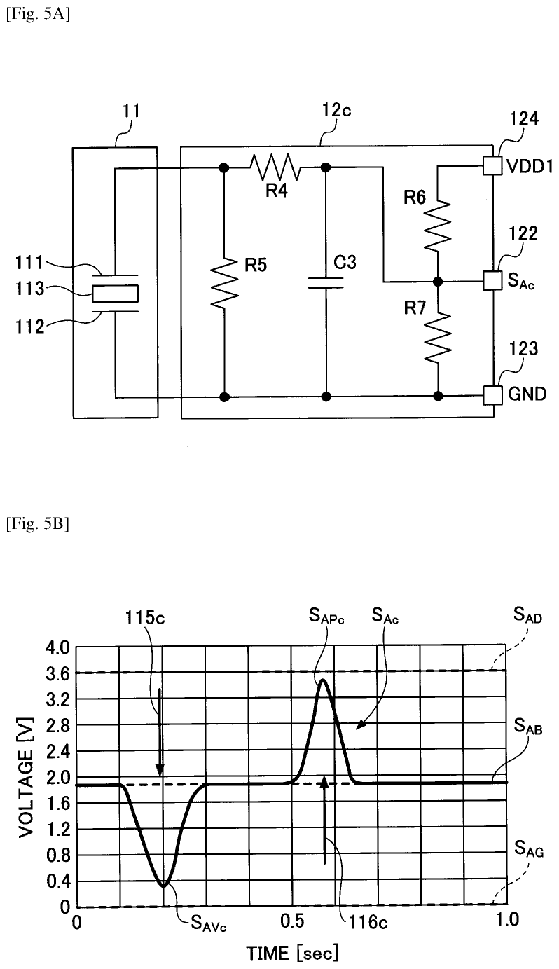

Next, FIGS. 5A and 5B are diagrams illustrating a fourth example of a signal conversion circuit, wherein FIG. 5A is a diagram illustrating an example of the configuration, and FIG. 5B is a graph illustrating an example of an output signal.

As illustrated in FIG. 5A, a signal conversion circuit 12c includes resistors R4 to R7, a capacitor C3, and a VDD terminal 124 to form a resistor-capacitor circuit (RC circuit).

Among these, the resistor R4 is coupled in series with respect to the charge generation rubber 11; one end on the side of the charge generation rubber 11 being coupled to the resistor R5, and the other end being coupled to the capacitor C3. The resistor R5 and the capacitor C3 are coupled, in parallel with each other, to the charge generation rubber 11.

The resistor R6 is coupled to the VDD terminal 124 at one end and to the output terminal 122 at the other end. The resistor R7 is coupled to the output terminal 122 at one end and to the GND terminal 123 at the other end.

By the voltage VDD1 input from the VDD terminal 124 and the signal conversion circuit 12c, an output signal S_{Ac}, using the reference voltage S_{AB} as a reference, is generated.

The signal conversion circuit 12c also functions as an impedance matching circuit that matches the output impedance of the signal conversion circuit 12c with the input impedance of the detecting unit 30 so that the output signal S_{Ac} of the signal conversion circuit 12c can be input to the detecting unit 30. The output impedance of the signal conversion circuit 12c can be adjusted by the resistance value of the resistors R4 to R7 and the capacitance value of the capacitor C3.

As illustrated in FIG. 5B, the output signal S_{Ac} is a signal using the reference voltage S_{AB} as a reference, and includes a peak voltage S_{AVc} in the negative direction and a peak voltage S_{APc} in the positive direction. This signal with peaks in the two directions of the positive direction and the negative direction can obtain the same effect as the output signal S_{A} described with reference to FIG. 2B.

The voltage S_{AD} in FIG. 5B corresponds to the voltage VDD1, and the voltage S_{AG} corresponds to the GND voltage. The range of voltages S_{AG} to S_{AD} corresponds to the dynamic range, and the reference voltage S_{AB} corresponds to a voltage value that is an intermediate value between the voltage S_{AG} and the voltage S_{AD}.

The dynamic range is adjusted to be within a range in which input is possible for the detecting unit 30 to perform A/D conversion, by the resistance values of the resistors R4 to R7 and the capacitance value of the capacitor C3. The reference voltage S_{AB} is adjusted to be within a range in which input is possible for the detecting unit 30 to perform A/D conversion, by a combination of the resistance values of the resistors R4 to R7.

The arrow 115c in FIG. 5B indicates the direction in which current flows at the time of the peak voltage S_{AVc} is the negative direction, and the arrow 116c indicates the direction in which current flows at the time of the peak voltage S_{APc} in the positive direction.

<Example of Detection Method by the Detecting Unit 30>

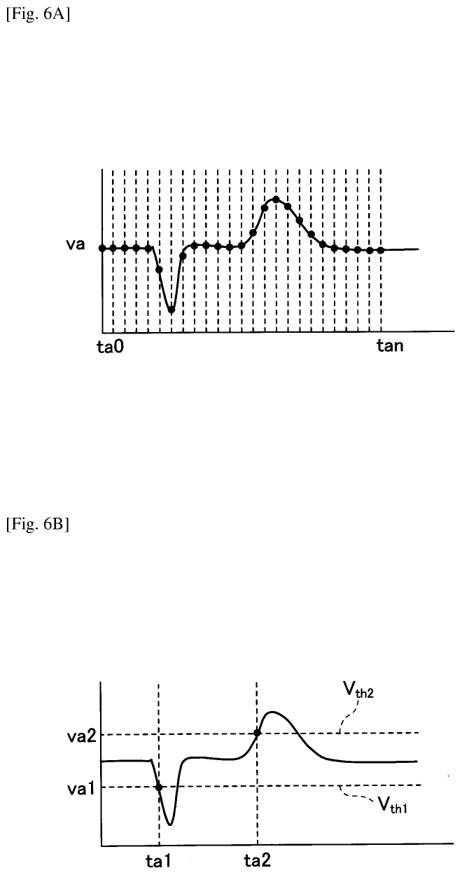

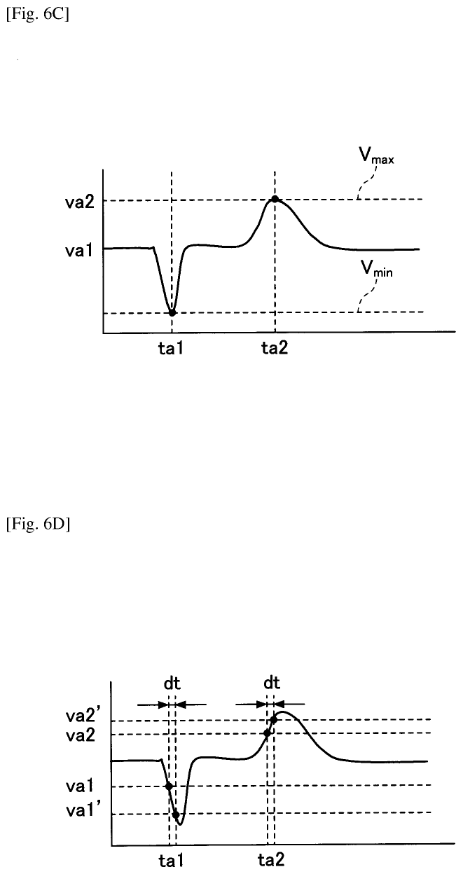

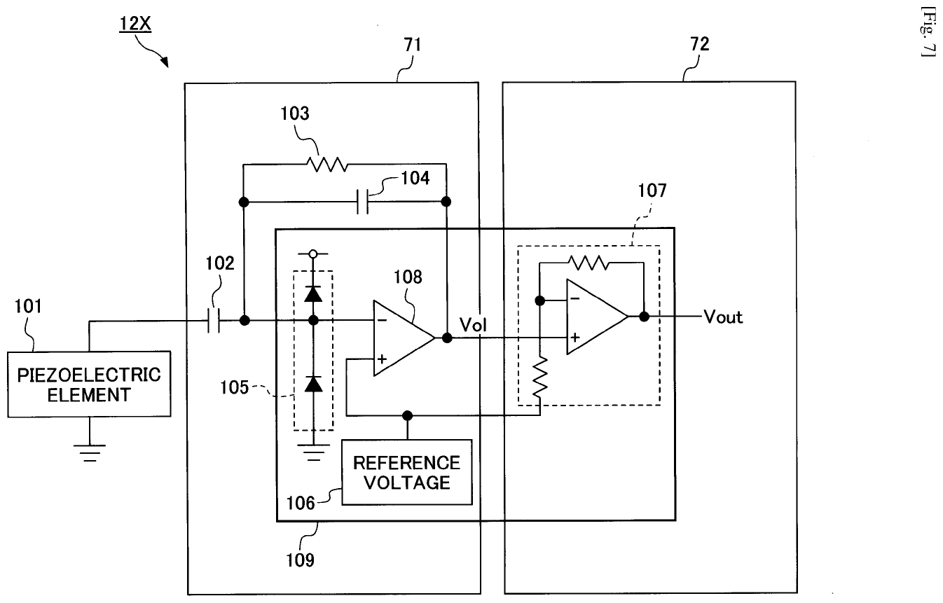

Next, a detection method by the detecting unit 30 will be described with reference to FIGS. 6A to 6D. The detecting unit 30 can execute any of the four detection methods described below with reference to FIGS. 6A to 6D. Any of the signal conversion circuits 12, and 12a to 12c may be applicable as a signal conversion circuit for supplying the output signal to the detecting unit 30. In the following, the signal conversion circuit 12 will be applied as an example.

Here, FIGS. 6A to 6D are graphs illustrating an example of a detection method by the detecting unit 30, wherein FIG. 6A is a graph illustrating a method using voltage value sampling, FIG. 6B is a graph illustrating a method using a threshold voltage, FIG. 6C is a graph illustrating a method using peak-hold, and FIG. 6D is a graph illustrating a method using a threshold differential voltage.

Further, in each graph illustrated in FIGS. 6A to 6D, the horizontal axis represents the time, and the vertical axis represents the voltage. A plot of a black circle in each graph represents the digital signal S_{D} detected by the detecting unit 30, and a graph of a solid line represents the output signal S_{A} input to the detecting unit 30.

In the method using voltage value sampling illustrated in FIG. 6A, the detecting unit 30 samples a voltage value va of the output signal S_{A} at predetermined sampling intervals Δt to perform A/D conversion, and detects (acquires) the voltage value and the time data at the corresponding time in association with each other.

Specifically, the detecting unit 30 detects (ta0, va1), (ta0+Δt, va2), (ta0+2?Δt, va3), . . . , (ta0+n?Δt, van). Here, ta0 represents the start time of the sampling, va represents the voltage value, n represents the total number of times of performing sampling, and the value that is the subscript of va represents the counter. In this example, the sampling has been performed 1 to n times.

With respect to the time data, the start time ta0 is used as the initial data, and every time sampling is performed, the sampling interval Δt is added to the initial data and the time data is detected. With respect to the voltage value, a voltage value van is detected in association with the time data.

Next, in the threshold voltage method of FIG. 6B, when the voltage of the output signal S_{A} crosses a predetermined threshold voltage value, the detecting unit 30 detects the voltage value and the time data at the corresponding time in association with each other.

In the example illustrated in FIG. 6B, a lower threshold voltage value Vₜₕ₁ and an upper threshold voltage value Vₜₕ₂ are predetermined. The voltage value va1 and the time data ta1 at the time when the output signal S_{A} crosses the lower threshold voltage value Vₜₕ₁, are detected in association with each other. The voltage value va2 and the time data ta2 at the time when the output signal S_{A} crosses the upper threshold voltage value Vₜₕ₂, are detected in association with each other.

Although only two data points are illustrated in FIG. 6B, the number of data points corresponding to the number of times of crossing either the lower threshold voltage value Vₜₕ₁ or the upper threshold voltage value Vₜₕ₂, is detected.

Next, in the method using peak-hold of FIG. 6C, the detecting unit 30 holds the voltage value at the time when the voltage value in the output signal S_{A} becomes the smallest and when the voltage value in the output signal S_{A} becomes the largest, and detects the voltage value and the time data at the corresponding time in association with each other.

In the example illustrated in FIG. 6C, the voltage value va1 at the time of the minimum value Vₘᵢₙ and the time data ta1 at the corresponding time are detected in association with each other, and the voltage value va2 at the time of the maximum value Vₘₐₓ and the time data ta2 at the corresponding time are detected in association with each other.

Next, in the differential voltage method illustrated in FIG. 6D, the time derivative value of the voltage value is detected.

In the example illustrated in FIG. 6D, Δva1(=va1−va1′), which is the voltage change amount during a minute time dt corresponding to time data ta1 (predetermined time), is detected. Further, Δva2(=va2−va2′), which is the voltage change amount during a minute time dt corresponding to time data ta2, is detected.

According to Δva1/ta1 and Δva2/ta2, it is possible to determine the strength of the foot stepping on the charge generation rubber 11 and the speed at which the foot is separated from the charge generation rubber 11, so that the state of walking can be recognized.

As described above, the detecting unit 30 can detect the output signal of the signal conversion circuit and output the detected digital signal S_{D} to the calculating unit 40.

<Effect of Function According to the First Embodiment>

(Effect of Function of the Signal Conversion Circuit 12)

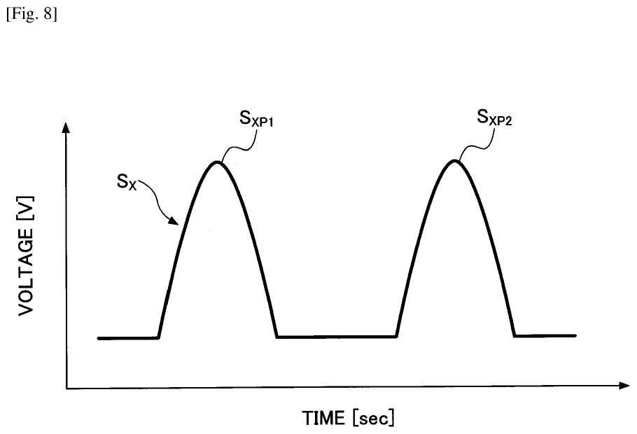

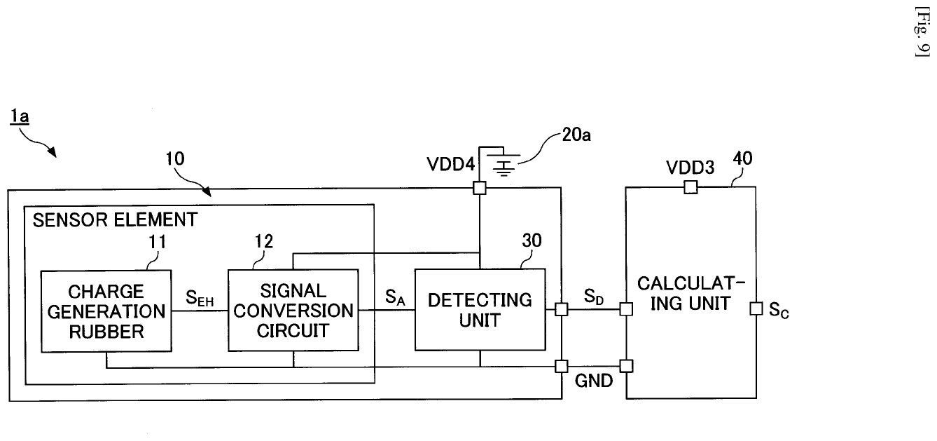

Next, an effect of the signal conversion circuit 12 provided in the sensor element 10 will be described. First, a signal conversion circuit 12X according to a comparative example will be described prior to the explanation of the effect of the signal conversion circuit 12. Here, FIG. 7 is a diagram illustrating a configuration of the signal conversion circuit 12X. FIG. 8 is a graph illustrating an output signal according to the comparative example.

As illustrated in FIG. 7, the signal conversion circuit 12X includes a piezoelectric element 101, an integrator circuit 71, and an amplifier circuit 72. The signal generated according to the charge of the piezoelectric element 101 as a charge generation element is input to the integrator circuit 71.

The integrator circuit 71 includes an integrator operational amplifier 108, and the generated signal is stored in a charge capacity 104 provided between the input and output of the integrator operational amplifier 108, and is converted to an integrated voltage signal Vo1.

At a later stage of the integrator operational amplifier 108, the amplifier circuit 72 is provided, which is coupled to a clockwise amplifier circuit 107 for amplifying the voltage signal Vo1 output from the integrator operational amplifier 108. The clockwise amplifier circuit 107 is also coupled to a reference voltage source 106.

The reference voltage source 106 provides a predetermined bias voltage to the integrator operational amplifier 108 and the clockwise amplifier circuit 107. The integrator operational amplifier 108, the clockwise amplifier circuit 107, and the reference voltage source 106 are integrated into an integrated circuit.

The signal conversion circuit 12X includes a function for converting a signal generated according to a charge of the piezoelectric element 101 into a predetermined signal and outputting the converted signal. However, the signal conversion circuit 12X performs signal conversion by using the integrator circuit 71 and the amplifier circuit 72 that are active elements, and, therefore, there are cases where the power consumption for signal conversion becomes large.

In contrast to such a comparison example, in the present embodiment, the signal conversion circuit 12 is configured only by a passive element. A passive element consumes less power than the active element, and, therefore, the signal conversion circuit 12 can reduce the power consumption in converting the signal S_{EH} generated according to the charge of the charge generation rubber 11 into the predetermined output signal S_{A}. Among passive elements, it is preferable to use a high impedance passive element than a low impedance passive element. Examples of high impedance passive elements include resistors, capacitors, and coils. By using a high impedance passive element, the power consumption can be reduced even more than when a low impedance passive element is used.

(Effect of Function of the Sensor System 1)

The sensor system 1 according to the present embodiment includes the detecting unit 30 for detecting an output signal of the sensor element 10. More specifically, the detecting unit 30 detects and outputs the digital signal S_{D}, by performing A/D conversion on the output signal S_{A} of the sensor element 10 that is an analog signal. This enables the analysis of the output signal S_{A} of the sensor element 10 by digital processing, and enables the digital data to be transmitted to an external device such as a personal computer (PC) or to be stored in a storage device.

The sensor system 1 includes the calculating unit 40 for analyzing the output signal of the sensor element 10. For example, the calculating unit 40 analyzes the output signal S_{A} of the sensor element 10 by digital processing and outputs the analysis data. Thus, various kinds of information can be acquired based on the output signal S_{A} of the sensor element 10.

In the present embodiment, an example of the sensor system 1 including both the detecting unit 30 and the calculating unit 40 is illustrated. However, the sensor system 1 may be configured to include either one of the detecting unit 30 or the calculating unit 40.

### Second Embodiment

Next, the sensor system 1a according to the second embodiment will be described.

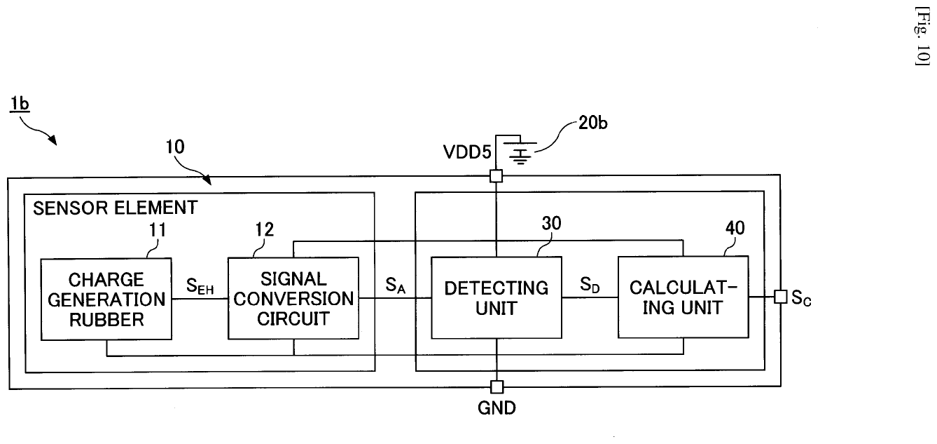

FIG. 9 is a block diagram illustrating an example of a configuration of a sensor system 1a. As illustrated in FIG. 9, the sensor system 1a includes a power source 20a.

The power source 20a supplies power to both the signal conversion circuit 12 and the detecting unit 30 in the sensor element 10. That is, the power supply source of the signal conversion circuit 12 and the power supply source of the detecting unit 30 are the same power source 20a.

The power source 20a applies a voltage VDD4 to both the signal conversion circuit 12 and the detecting unit 30 to supply power. The power source 20a may be formed of a primary battery, a secondary battery, a capacitor, and the like.

Thus, by making the power supply source of the signal conversion circuit 12 and the power supply source of the detecting unit 30 be the same power source 20a, the signal conversion circuit 12 can output the output signal S_{A} at the dynamic range required for the output signal S_{A} of the signal conversion circuit 12 to be input to the detecting unit 30.

FIG. 9 illustrates an example of the sensor system 1a in which the power supply source of the signal conversion circuit 12 and the power supply source of the detecting unit 30 are the same power source 20a; however, the present embodiment is not limited thereto. The sensor system 1a may be configured so that the power supply source of the signal conversion circuit 12 and the power supply source of the calculating unit 40 are the same power source. In this case, the signal conversion circuit 12 can output the output signal S_{A} at the dynamic range required for the output signal S_{A} of the signal conversion circuit 12 to be input to the calculating unit 40.

Further, the sensor system may be configured such that all of the power supply sources of the signal conversion circuit 12, the detecting unit 30, and the calculating unit 40 are the same power source. FIG. 10 is a block diagram illustrating the configuration of a sensor system 1b that is another example of the sensor system. The power supply source of all of the signal conversion circuit 12, the detecting unit 30, and the calculating unit 40 in the sensor system 1b are the same power source.

As illustrated in FIG. 10, the sensor system 1b includes a power source 20b for supplying power to all of the signal conversion circuit 12, the detecting unit 30, and the calculating unit 40. That is, all of the power supply sources of the signal conversion circuit 12, the detecting unit 30, and the calculating unit 40 are the same power source 20b.

The power source 20b applies a voltage VDD5 to all of the signal conversion circuit 12, the detecting unit 30, and the calculating unit 40 to supply power. The power source 20b may be configured by a primary battery, a secondary battery, a capacitor, and the like.

With such a configuration, the dynamic range of the signal conversion circuit 12, the detecting unit 30, and the calculating unit 40 in the sensor system 1b can be easily matched.

### Third Embodiment

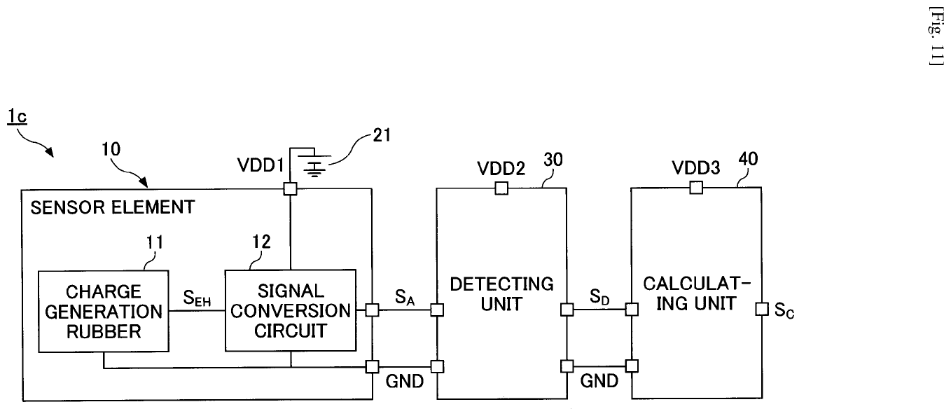

Next, a sensor system 1c according to a third embodiment will be described. FIG. 11 is a block diagram illustrating an example of a configuration of the sensor system 1c.

As illustrated in FIG. 11, the sensor system 1c includes a secondary battery 21 as a power source to supply power to the signal conversion circuit 12 in the sensor element 10. The secondary battery 21 is formed of a lithium ion battery, a lead storage battery, and the like.

Here, the secondary battery 21 has a voltage output characteristic (a discharge characteristic) wherein the change in voltage of the output signal accompanying a change in the State of Charge (SOC) and the like, which is the remaining capacity of a power storage element, is small, compared to those of other power storage elements such as capacitors and condensers. That is, the secondary battery 21 can reduce the changes in the output voltage even when the SOC changes due to the charging or discharging of the secondary battery 21.

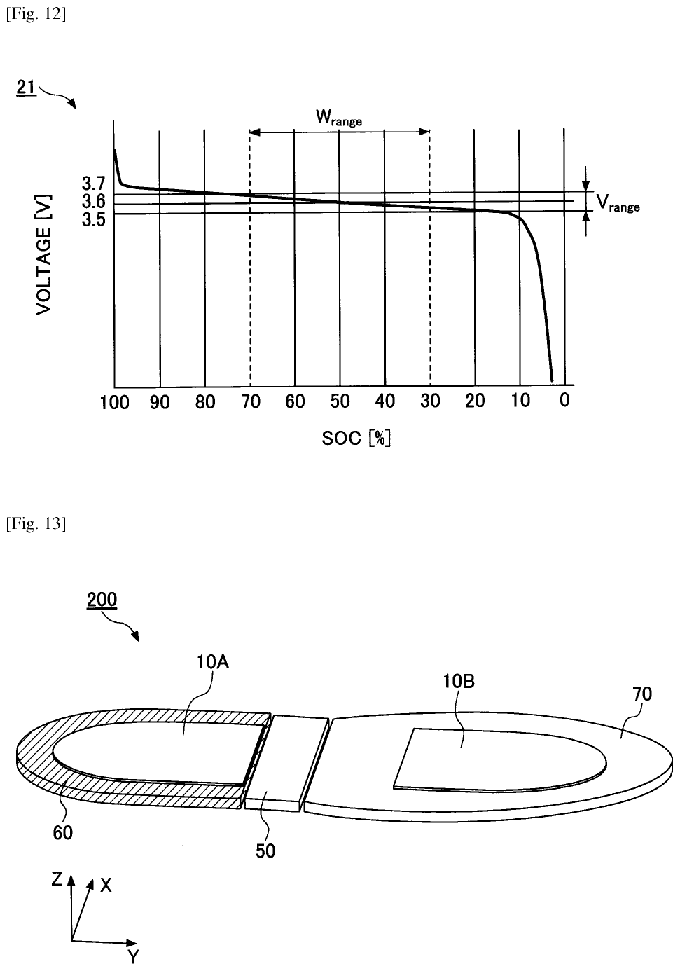

FIG. 12 is a graph illustrating an example of a voltage output characteristic of the secondary battery 21. In FIG. 12, The horizontal axis represents the SOC of the secondary battery 21 and the vertical axis represents the output voltage of the secondary battery 21. In FIG. 12, W_{range} represents the power usage range used by the signal conversion circuit 12 among the power supplied by the secondary battery 21. Further, V_{range} represents the range of the change in the output voltage corresponding to the power usage range W_{range}.

As illustrated in FIG. 12, in the voltage output characteristic of the secondary battery 21, the voltage change associated with the SOC has a flat region where the slope is small. For example, in the example of FIG. 12, the range where the SOC is 10% or more and 90% or less, etc., corresponds to a flat region where the slope is small in the voltage change associated with the SOC.

Using this region, by setting, in advance, the power usage range W_{range} used by the signal conversion circuit 12 to be a range in which the SOC is 10% or more and 90% or less, the voltage change range V_{range} can be a narrow range of 3.5 V or more and 3.7 V or less. Accordingly, changes in output voltage associated with the SOC can be reduced. Here, “a range in which the SOC is 10% or more and 90% or less” is an example of a “predetermined range”.

When the change in the output voltage of the power source supplying power to the signal conversion circuit 12 is large, the driving voltage supplied to the signal conversion circuit 12 will change, and, therefore, the signal conversion circuit 12 may fail to operate normally. In contrast, in the present embodiment, the secondary battery 21 is used as the power source, and the power usage range W_{range} in which the voltage change associated with the SOC has a small slope, is predetermined as the power use range. By using the power within this power usage range W_{range}, the change in the output voltage associated with the SOC can be reduced, and the signal conversion circuit 12 can be operated stably and normally.

In the present embodiment, the secondary battery 21 supplies power to the signal conversion circuit 12 as an example, but the present invention is not limited thereto. The sensor system 1c may be configured so that the secondary battery 21 supplies power to at least one of the detecting unit 30 and the calculating unit 40 in addition to the signal conversion circuit 12. That is, the power source 20a in FIG. 9 or the power source 20b in FIG. 10 may be configured by the secondary battery 21. In this case, by reducing the changes in the output voltage associated with the SOC, at least one of the detecting unit 30 and the calculating unit 40 in addition to the signal conversion circuit 12 can be operated stably and normally.

In the present embodiment, the signal conversion circuit 12 is illustrated as an example, but the same effect can be obtained when the present embodiment is applied to the signal conversion circuits 12a to 12c.

### Fourth Embodiment

Next, an insole 200 according to a fourth embodiment will be described.

Here, the term “insole” refers to a cushion that is used in footwear such as shoes and that has elasticity, and is also referred to as an inner sole. The insole can be formed of materials such as polyurethane, polyester, wool, leather, activated carbon, and the like.

<Overall Configuration Example of the Insole 200>

FIG. 13 is a diagram illustrating an example of the overall configuration of the insole 200 according to the present embodiment. The X direction illustrated in FIG. 13 corresponds to the short direction (the width direction) of the insole 200, and the Y direction corresponds to the longitudinal direction of the insole 200. The Z direction is orthogonal to both the X direction and the Y direction.

As illustrated in FIG. 13, the insole 200 includes sensor elements 10A and 10B, a processing unit 50, and a power generating unit 60. In this configuration example, the two sensor elements 10A and 10B are used as the sensor elements, but the number of the sensor elements is not particularly limited as long as a plurality of sensor elements are used. The portion on the side on the toe (hereinafter referred to as the toe portion) corresponding to the positive Y direction side of the insole 200 includes a material portion 70 formed of the insole material. The portion on the side on the heel (hereinafter referred to as the heel portion) corresponding to the negative Y direction side of the insole 200 includes the power generating unit 60 (the hatched portion of diagonal lines). The processing unit 50 is provided between the material portion 70 and the power generating unit 60 in the Y direction so as to connect the material portion 70 with the power generating unit 60.

Each of the sensor elements 10A and 10B has the same functions as the sensor element 10 described in the first to third embodiments, and is an element that converts the charge, which is generated in response to an external stimulus, for example, external stress such as pressure in the present embodiment, into a predetermined output signal, and outputs the output signal. The sensor element 10A outputs an output signal S_{A1} and the sensor element 10B outputs an output signal S_{A2}. The output signals S_{A} and S_{B} correspond to detection signals of detecting pressure, etc.

The sensor element 10A is disposed on the surface on the positive Z direction side of the power generating unit 60 at the heel portion of the insole 200. The sensor element 10B is disposed on the surface on the positive Z direction side of the material portion 70 at the toe portion of the insole 200. Here, the surface on the positive Z direction side of the insole 200 is the surface on the side where the sole of the user (hereinafter referred to as the insole user) contacts when the insole user wears the footwear in which the insole 200 is mounted. The surface on the negative Z direction side of the insole 200 is the surface on the side that contacts the footwear to which the insole 200 is mounted.

By fixing the sensor element 10A to the surface of the power generating unit 60, the sensor element 10A can be disposed on the insole 200. By fixing the sensor element 10B to the surface of the material portion 70, the sensor element 10B can be disposed on the insole 200. These elements can be fixed by adhesives, double-sided tape, and the like.

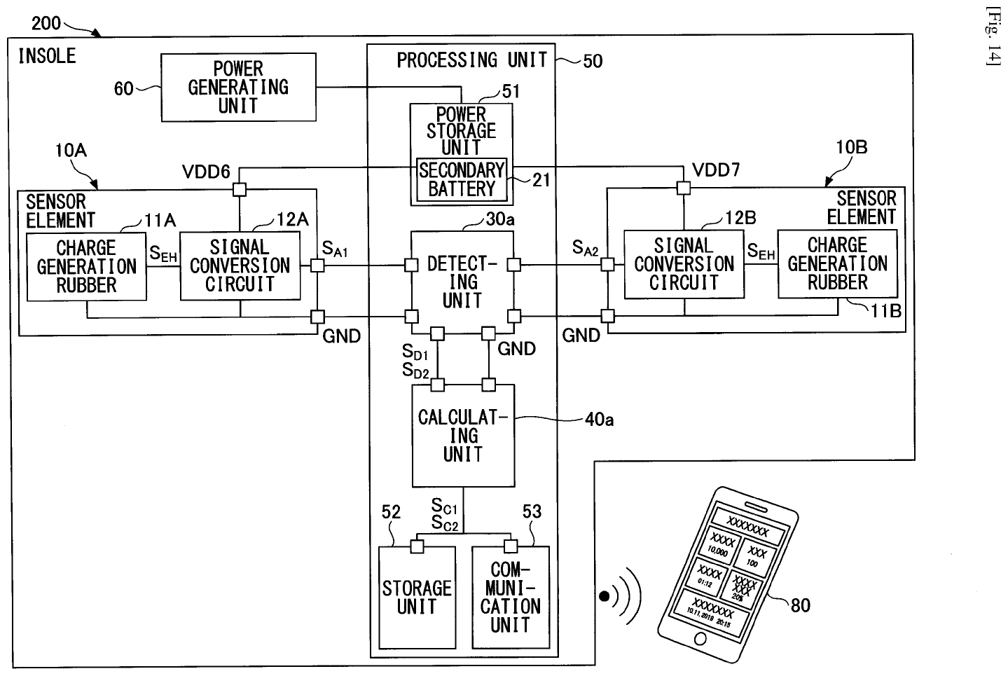

The processing unit 50 is an electrical circuit that receives the output signals of the sensor elements 10A and 10B and executes predetermined processes on the output signals. Details of the configuration and functions of the processing unit 50 are described in detail with reference to FIG. 14 below.

The power generating unit 60 may include a power generation rubber and the like to generate power in response to an external stimulus. More specifically, the power generating unit 60 formed of rubber or a rubber composition, and includes a plurality of stacks of power generating elements, in which an intermediate layer which is a flexible layer is sandwiched between a pair of electrodes. The number of layers of the power generating elements may be, for example, 10 layers.

The power generating unit 60 generates power upon receiving pressure that is applied as the insole user walks, etc., and supplies the generated power to the secondary battery provided in the processing unit 50.

The arrangement of the sensor elements 10A and 10B, the processing unit 50, the power generating unit 60, and the like in the insole 200 is not limited to those described above, and various modifications are possible.

For example, the portions where the sensor elements 10A and 10B are disposed are not limited to the surface on the positive Z direction side of the insole 200, but may be the surface on the negative Z direction side of the insole 200 or inside the base (material) of the insole 200. The sensor element 10A and the sensor element 10B may be disposed on different portions of the insole 200, for example, the sensor element 10A may be disposed on the positive Z direction side of the insole 200 and the sensor element 10B may be disposed inside the insole 200. Preferably, however, the portions where the sensor element 10A and the sensor element 10B are fixed are aligned in order to match the detection conditions between the sensor element 10A and the sensor element 10B.

Further, the entire insole 200 may be configured by the material portion 70, and at least one of the processing unit 50 and the power generating unit 60 may be disposed on the surface of or inside the material portion 70. The sensor elements 10A and 10B, the processing unit 50, and the power generating unit 60 may each be covered with an accommodating member. The material, shape, size, and structure of the accommodating member are not particularly limited and may be selected as appropriate depending on the purpose.

### <Example Configuration of the Processing Unit 50>

Next, the processing unit 50 will be described. FIG. 14 is a block diagram illustrating an example of a configuration of the processing unit 50 included in the insole 200. As illustrated in FIG. 14, the processing unit 50 includes a power storage unit 51, a detecting unit 30a, a calculating unit 40a, a storage unit 52, and a communication unit 53, and forms an electrical circuit.

The sensor element 10A includes a charge generation rubber 11A that generates a charge in response to an external stimulus and a signal conversion circuit 12A that converts the charge generated by the charge generation rubber 11A into a predetermined output signal. The sensor element 10B includes a charge generation rubber 11B that generates a charge in response to an external stimulus and a signal conversion circuit 12B that converts the charge generated by the charge generation rubber 11B into a predetermined output signal.

The power storage unit 51 includes the secondary battery 21, and stores the power generated by the power generating unit 60 in the secondary battery 21, and supplies the stored power to the sensor element 10A, the sensor element 10B, the detecting unit 30a, the calculating unit 40a, the storage unit 52, and the communication unit 53.

The function of the power storage unit 51 to supply power to the sensor elements 10A and 10B, the detecting unit 30a, and the calculating unit 40a is the same as the function of the power source 20b to supply power to the sensor element 10, the detecting unit 30, and the calculating unit 40 described in the second embodiment (see FIG. 10). The function of the secondary battery 21 is the same as that described in the third embodiment (see FIGS. 11 and 12).

The power storage unit 51 can supply power to the sensor element 10A by applying a voltage VDD6, and can also supply power to the sensor element 10B by applying a voltage VDD7. In FIG. 14, the VDD terminal for the power storage unit 51 to supply power to the detecting unit 30a, the calculating unit 40a, the storage unit 52, and the communication unit 53; and the GND terminal for installation, are not illustrated.

In addition to the secondary battery 21, the power storage unit 51 may include a plurality of power storage devices, such as a capacitor, and a series-parallel switching unit that switches the connection state of the plurality of power storage devices between series connection and parallel connection. By including a plurality of power storage devices and the series-parallel switching unit, the power storage efficiency of the power storage unit 51 can be increased. The known technology disclosed in Japanese Unexamined Patent Application Publication No. 2019-161975, etc., can be applied to such a configuration, so a more detailed description thereof will be omitted.

The detecting unit 30a is an electrical circuit that detects an output signal S_{A1} of the signal conversion circuit 12A by A/D conversion and outputs a digital signal S_{D1} to the calculating unit 40. The detecting unit 30a also detects an output signal S_{A2} of the signal conversion circuit 12B by A/D conversion and outputs a digital signal S_{D2} to the calculating unit 40.

The calculating unit 40a is a processor configured by a central processing unit (CPU) and the like, that executes an analysis process on the digital signals S_{D1} and S_{D2} input from the detecting unit 30a, and outputs corresponding analysis data S_{C1} and S_{C2} to the storage unit 52 and the communication unit 53.

This analysis process is performed to obtain the heel landing rate and the like based on the detection signals output from the sensor elements 10A and 10B by detecting the pressure applied to the insole 200. Here, the heel landing rate refers to the ratio at which the heel lands on the ground while the insole user is walking.

The power consumption for calculation can be reduced by using a processor which operates the functions of the detecting unit 30a and the calculating unit 40a at low voltage and low current, and, therefore, such a processor is suitable when applying the sensor system including the insole 200, the sensor elements 10A and 10B, and the processing unit 50 to Internet of Things (IoT) applications, etc.

The storage unit 52 is a memory for storing analysis data S_{C1} and S_{C2}. The storage unit 52 may be configured with a semiconductor memory or a portable memory such as a Universal Serial Bus (USB) memory. When the storage unit 52 is configured with a portable memory, the storage unit 52 is suitable when transferring the stored analysis data S_{C1} and S_{C2} to an external device such as a PC.

The communication unit 53 is a communication circuit such as Near Field Communication (NFC) or Bluetooth (registered trademark) that wirelessly transmits the analysis data S_{C1} and S_{C2} to a smartphone 80. The communication unit 53 may also receive signals and data wirelessly from the smartphone 80. Usage of the Bluetooth Low Energy (BLE) standard as a wireless communication protocol reduces power consumption for communication, and is thus suitable for IoT applications. Here, the communication unit 53 is an example of the transmitter.

In the smartphone 80, an application for analyzing how weight is applied to the sole of the foot while the insole user is walking, running, standing, and the like, based on the analysis data S_{C1} and S_{C2} received from the insole 200, is installed.

The insole user can use the smartphone 80 and the above-described application to analyze features such as how weight is applied, how the insole user walks, runs, and the like based on the analysis data S_{C1} and S_{C2}.

The target device with which the communication unit 53 communicates is not limited to the above-described smartphone 80, but may be an external device such as a PC, a server, a display, and the like.

<Example of Analysis Data>

Next, the analysis data S_{C1} and S_{C2} detected by the sensor elements 10A and 10B and output from the processing unit 50 will be described.

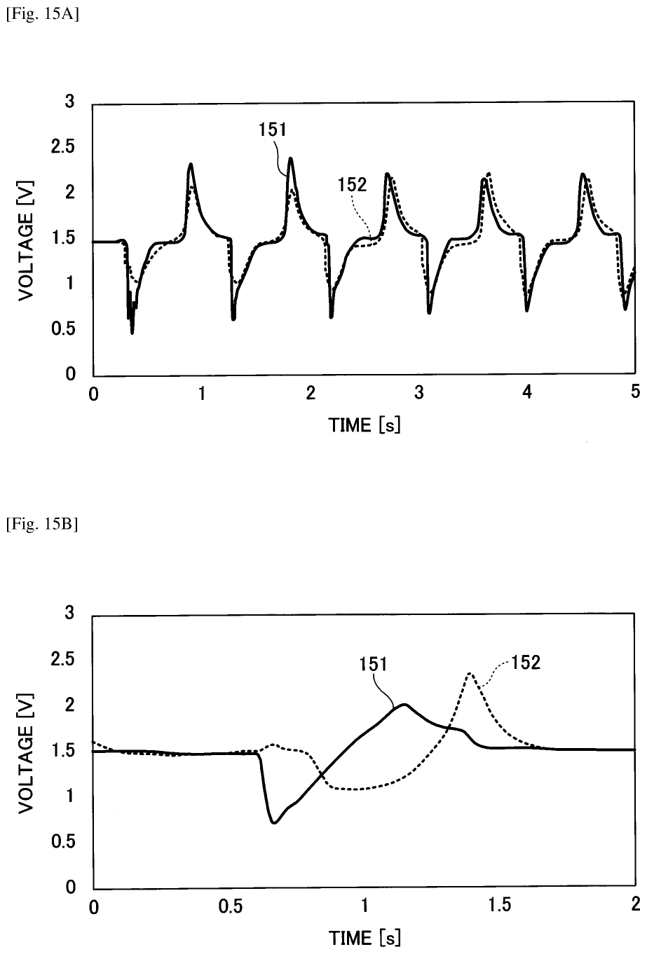

FIGS. 15A and 15B are graphs illustrating an example of the analysis data S_{C1} and S_{C2} obtained by the processing unit 50. FIG. 15A is a graph illustrating a case where the insole user steps on the spot, and FIG. 15B is a graph illustrating a case where the insole user advances one step forward.

The horizontal axis of the graph represents time, and the vertical axis represents voltage. A solid graph line 151 represents the analysis data S_{C1} based on the output signal S_{A1} of a sensor element 10a (heel portion), and a dashed graph line 152 illustrates the analysis data S_{C2} based on the output signal S_{A2} of a sensor element 10b (toe portion).

When the insole user steps on the spot, the entire sole of insole user is separated from the ground at about the same timing, and the force applied on the entire sole is about the same overall. Thus, substantially the same amount of pressure is applied to the heel portion and the toe portion of the insole 200, and, therefore, the output signal S_{A1} of the sensor element 10a and the output signal S_{A2} of the sensor element 10b are substantially the same. As a result, the graph line 151 and the graph line 152 are substantially overlapping each other, as illustrated in FIG. 15A. In the example of FIG. 15A, the voltage signal representing the pressure is repeatedly displayed in five waveforms according to the stepping motion repeatedly performed five times.

On the other hand, in a case where the insole user walks a step forward, when the insole user first lifts his or her foot, the toe portion of the sole of the foot applies pressure on the ground, and the heel portion is separated from the ground. Then, when the raised foot contacts the ground, the heel portion first contacts the ground and then the toe portion contacts the ground.

According to the movement of the sole of the foot relative to the ground, when the insole user raises his or her foot, pressure is applied to the toe portion and the pressure on the heel portion is reduced. Then, when the lifted foot lands on the ground, the pressure on the heel portion is increased, and subsequently the pressure on the toe portion is increased. As illustrated in FIG. 15B, according to the difference in pressure applied to the heel portion and toe portion, the graph line 151 and the graph line 152 are illustrated separately.

Based on such analysis data S_{C1} and S_{C2}, the smartphone 80 can analyze features such as how weight is applied to the sole, how the insole user walks, runs, and the like, while the insole user is walking, running, standing, and the like.

Note that although the example illustrated in FIGS. 13 to 15B illustrates the application of the insole 200 to one foot, the same insole 200 may be applied to both feet. By acquiring the analysis data of both feet while the insole user is walking, running, standing, and the like, it is possible to analyze how the insole user walks, etc., in more detail.

<Functional Effect According to the Fourth Embodiment>

As described above, in the present embodiment, the insole 200 is configured by including the sensor element 10A including the charge generation rubber 11A that generates a charge in response to an external stimulus, and the signal conversion circuit 12A that converts the charge generated by the charge generation rubber 11A into a predetermined output signal. Accordingly, the pressure applied to the insole 200 can be detected based on the output signal S_{A1} of the signal conversion circuit 12A, and an insole capable of detecting pressure can be provided.

Further, in the present embodiment, the sensor element 10A is configured to include the charge generation rubber 11A. The charge generation rubber 11A is elastic and soft, and, therefore, the insole user can comfortably wear footwear in which the insole 200 is mounted. Further, the elasticity and softness of the charge generation rubber 11A prevent the sensor element 10A from breaking, and, therefore, failures, breakage and the like of the sensor element 10A can be reduced, and the need for replacing or repairing the sensor element 10A can be reduced, thereby improving the maintenance properties.

Further, the signal conversion circuit 12A is configured only of a passive element, and, therefore, the power consumption for signal conversion is very low. Therefore, the power consumption of the insole 200 can be reduced. In the present invention, a “passive element” means an element that does not have an active function such as amplification or conversion of electrical energy, including elements such as a resistor, a capacitor, or a coil. An active element means an element that has an active function such as amplification or conversion of electrical energy, including elements such as an operational amplifier or a voltage follower. Among various passive elements, the passive element used herein is preferably a high impedance passive element, rather than a low impedance passive element. High impedance passive elements include, for example, resistors, capacitors, and coils. By using a high impedance passive element, the power consumption can be reduced more than when a low impedance passive element is used. Further, by using a passive element having high impedance, the impedance of the signal conversion circuit 12A can be increased, and even when a charge generation elastic body having a high output impedance such as a charge generation rubber is used, all of the voltage waveforms of the power output by the charge generation elastic body can be easily included in the dynamic range (effective voltage range).

Further, the sensor element 10A, the sensor element 10B, the detecting unit 30a, the calculating unit 40a, the storage unit 52, and the communication unit 53 in the insole 200 are supplied with driving power from the power storage unit 51 that stores the power generated by the power generating unit 60. This eliminates the need for an external power source for supplying the driving power for each of the elements.

The low power consumption and the elimination of the need for an external power source are particularly suitable for applying the insole 200 to an IoT application.

Further, in the present embodiment, a plurality (two in this example) of sensors, i.e., the sensor element 10A and the sensor element 10B, are provided at different positions of the insole 200. Thus, the pressure applied to different positions of the insole 200 can be detected, and it is possible to analyze, in greater detail, features such as how weight is applied to the sole, how the insole user walks, runs, and the like.

However, the number of sensor elements to be installed is not limited to two, and there may be three or more sensor elements. The more the number of sensor elements, the more detailed the analysis will be possible.

In the present embodiment, a plurality (two in this example) of sensors, i.e., the sensor element 10A and the sensor element 10B are provided at different positions of the insole 200, but more sensor elements can be disposed at multiple locations to perform more detailed analysis of features such as walking and running. Thus, the changes in pressure applied to different positions of the insole 200 can be detected, and it is possible to analyze, in greater detail, features such as how weight is applied to the sole, how the insole user walks, runs, and the like.

As a matter of course, the location of disposing the sensor element on the insole 200 is not limited to the toe side and the heel side as described above, but may be disposed at any location depending on the analysis data to be acquired.

Further, the present embodiment includes a processor for outputting analysis data S_{C1} and S_{C2} acquired based on output signals S_{A1} and S_{A2} of the sensor elements 10A and 10B. This allows the desired processing to be executed on the digital data of the output signals S_{A1} and S_{A2}. It is also possible to control various units such as the sensor elements 10A and 10B and the detecting unit 30a.

In the present embodiment, the storage unit 52 for storing the analysis data S_{C1} and the S_{C2} is provided. This enables storage of analysis data S_{C1} and S_{C2} and the extraction of the stored data.

According to the present embodiment, there is provided the communication unit 53 that wirelessly transmits the analysis data S_{C1} and S_{C2}. Thus, the analysis data S_{C1} and S_{C2} can be provided to an external device such as the smartphone 80, and the analysis data S_{C1} and S_{C2} can be stored in an external device, and detailed analysis can be performed on how the insole user walks and runs, etc., by the external device.

### Fifth Embodiment

Next, the footwear according to the fifth embodiment will be described.

Examples of footwear include sneakers, leather shoes, pumps, high heels, slip-ons, sandals, slippers, boots, mountaineering shoes, sports shoes, shoes, indoor shoes, wooden clogs, Japanese sandals, Japanese socks, and the like.

<Overall Configuration Example of the Footwear 300>

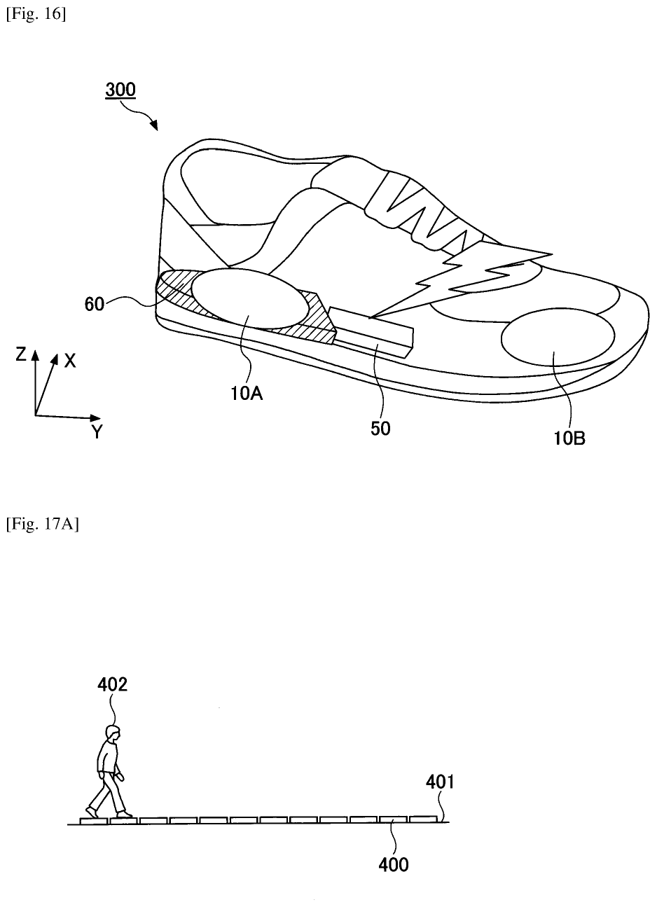

FIG. 16 is a diagram illustrating an example of the overall configuration of the footwear 300 according to the present embodiment. Note that in FIG. 16, the X direction corresponds to the shorter direction (the width direction) of the footwear 300, and the Y direction corresponds to the longitudinal direction of the footwear 300. The Z direction is orthogonal to both the X direction and the Y direction.

As illustrated in FIG. 16, the footwear 300 includes the sensor elements 10A and 10B, the processing unit 50, and the power generating unit 60. The sensor element 10B is provided on the toe portion side corresponding to the positive Y side of the footwear 300. The power generating unit 60 (the hatched portion of diagonal lines) and the sensor element 10A are provided on the heel portion side corresponding to the negative Y direction side of the footwear 300. The processing unit 50 is provided between the sensor element 10A and the sensor element 10B in the Y direction.

The sensor element 10A is disposed on the surface on the positive Z direction side of the power generating unit 60 provided at the inner bottom of the heel portion of the footwear 300. The inner bottom refers to the inside of the bottom of the footwear 300. The sensor element 10B is disposed at the inner bottom of the toe portion of the footwear 300. The inner bottom portion of the footwear 300 is the portion on the side where the sole of the user (hereinafter referred to as the footwear user) contacts when the footwear user wears the footwear 300. The outer bottom portion of the footwear 300 is the portion on the side of the footwear 300 that contacts the ground. The outer bottom portion refers to the outside of the bottom of the footwear 300.

The sensor element 10A can be disposed on the footwear 300 by fixing the sensor element 10A to the surface on the positive Z direction side of the power generating unit 60, and the sensor element 10B can be disposed on the footwear 300 by fixing the sensor element 10B to the inner bottom. The fixing can be done by using by adhesives, double-sided tape, and the like.

The arrangement of the sensor elements 10A and 10B, the processing unit 50, the power generating unit 60, and the like in the footwear 300 is not limited to those described above, and various kinds of modifications are possible.

For example, the portions where the sensor elements 10A and 10B are disposed are not limited to the inner bottom portion of the footwear 300, but may be the outer bottom portion of the footwear 300 or the interior portion of the base (material) that constitutes the bottom portion of the footwear 300.

The sensor element 10A and the sensor element 10B may be disposed at different portions of the footwear 300, for example, the sensor element 10A may be disposed at the inner bottom of the footwear 300 and the sensor element 10B may be disposed at the outer bottom of the footwear 300. However, the portions where the sensor element 10A and the sensor element 10B are fixed are preferably aligned in order to match the detection conditions between the sensor element 10A and the sensor element 10B.

The sensor elements 10A and 10B, the processing unit 50, and the power generating unit 60 may also be covered with a member to accommodate each of these elements. The material, the shape, the size, and the structure of the member for accommodating the elements are not particularly limited and may be selected as appropriate depending on the purpose.

Further, by mounting the insole 200 described in the fourth embodiment to the footwear 300, the sensor elements 10A and 10B, the processing unit 50, and the power generating unit 60 can be disposed in the footwear 300.

The structure and functions of the sensor elements 10A and 10B, the processing unit 50, and the power generating unit 60, the output signal, the analysis data, and the like are the same as those described in the fourth embodiment, and, therefore, overlapping descriptions are omitted herein.

<Functional Effect According to the Fifth Embodiment>

As described above, in the present embodiment, the footwear 300 is configured by including the sensor element 10A including the charge generation rubber 11A that generates a charge in response to an external stimulus and the signal conversion circuit 12A that converts the charge generated by the charge generation rubber 11A into a predetermined output signal. Accordingly, the pressure applied on the footwear 300 can be detected based on the output signal S_{A1} of the signal conversion circuit 12A.

Further, in the present embodiment, the sensor element 10A is configured to include the charge generation rubber 11A. The charge generation rubber 11A is elastic and soft, and, therefore, the footwear user can comfortably wear the footwear 300. Further, the elasticity and softness of the charge generation rubber 11A prevent the sensor element 10A from breaking, and, therefore, failures, breakage and the like of the sensor element 10A can be reduced, and the need for replacing or repairing the sensor element 10A can be reduced, thereby improving the maintenance properties.

Further, the signal conversion circuit 12A is configured only of a passive element, and, therefore, the power consumption for signal conversion is very low. Thus, the power consumption of the footwear 300 can be reduced. The definition and significance of passive elements are similar to those described in the fourth embodiment.

The sensor element 10A, the sensor element 10B, the detecting unit 30a, the calculating unit 40a, the storage unit 52, and the communication unit 53 in the footwear 300 are supplied with driving power from the power storage unit 51 that stores the power generated by the power generating unit 60. This eliminates the need for an external power source for supplying the driving power for each of the elements.

The low power consumption and the elimination of the need for an external power source are particularly suitable for applying the footwear 300 to an IoT application.

Further, in the present embodiment, a plurality (two in this example) of sensors, i.e., the sensor element 10A and the sensor element 10B, are provided at different positions of the footwear 300. Thus, the pressure applied to different positions of the footwear 300 can be detected, and it is possible to analyze, in greater detail, features such as how weight is applied to the sole, how the footwear user walks, runs, and the like.

However, the number of sensor elements to be installed is not limited to two, and there may be three or more sensor elements. The more the number of sensor elements, the more detailed the analysis will be possible.

In the present embodiment, a plurality (two in this example) of sensors, i.e., the sensor element 10A and the sensor element 10B are provided at different positions of the footwear 300, but more sensor elements can be disposed at multiple locations to perform more detailed analysis of features such as walking and running. Thus, the changes in pressure applied to different positions of the footwear 300 can be detected, and it is possible to analyze, in greater detail, features such as how weight is applied to the sole, how the footwear user walks, runs, and the like.

As a matter of course, the location of disposing the sensor element in the footwear 300 is not limited to the toe side and the heel side as described above, but may be disposed at any location depending on the analysis data to be acquired.

Further, the present embodiment includes a processor for outputting analysis data S_{C1} and S_{C2} acquired based on output signals S_{A1} and S_{A2} of the sensor elements 10A and 10B. This allows the desired processing to be executed on the digital data of the output signals S_{A1} and S_{A2}. It is also possible to control various units such as the sensor elements 10A and 10B and the detecting unit 30a.

In the present embodiment, the storage unit 52 for storing the analysis data S_{C1} and the S_{C2} is provided. This enables storage of analysis data S_{C1} and S_{C2} and the extraction of the stored data.

According to the present embodiment, there is provided the communication unit 53 that wirelessly transmits the analysis data S_{C1} and S_{C2}. Thus, the analysis data S_{C1} and S_{C2} can be provided to an external device such as the smartphone 80, and the analysis data S_{C1} and S_{C2} can be stored in an external device, and detailed analysis can be performed on how the footwear user walks and runs, etc., by the external device.

### Sixth Embodiment

Next, a pressure-type passage sensor according to the sixth embodiment will be described. Here, a pressure-type passage sensor is a sensor that detects the passage of a person or an object based on the pressure caused by a person or an object such as a vehicle.

For example, a pressure-type passage sensor may be provided inside a building or on the floor outside the building near the building. The pressure-type passage sensor detects the pressure applied as the person entering or exiting the building or a room steps on the pressure-type passage sensor by his or her foot, thereby detecting the entry and exit of a person into or from the building or room. However, the pressure-type passage sensor is not limited to detecting the entry and exit, and can detect various cases of passing persons by detecting the pressure applied as a passing person steps on the sensor with his or her foot. Such a pressure-type passage sensor can also be referred to as a floor sensor.

The target to be detected by the pressure-type passage sensor may not only be a person but also a mobile body, such as a vehicle. For example, a pressure-type passage sensor may be provided on the ground surface of the parking lot. By detecting the pressure applied by the tire of the a vehicle entering or exiting into or out of the parking lot, the pressure-type passage sensor can detect the entry and exit of a vehicle into and out of the parking lot. The pressure-type passage sensor is not limited to detecting the entry and exit, for example, the pressure-type passage sensor may be provided near a parking space where a vehicle is to be parked within a parking lot, and the entry and exit of the vehicle into and out of the parking space can be detected by the pressure-type passage sensor.

Mobile bodies are not limited to vehicles, and may be, for example, automatic conveying vehicles. The pressure-type passage sensor is provided on the floor or the ground surface of the passage path of the automatic conveying vehicle, and by detecting the pressure applied on the pressure-type passage sensor by the tire of the automatic conveying vehicle, the pressure-type passage sensor can detect the passage of the automatic conveying vehicle.

<Typical Example of Passage Detection by Pressure-Type Passage Sensor>

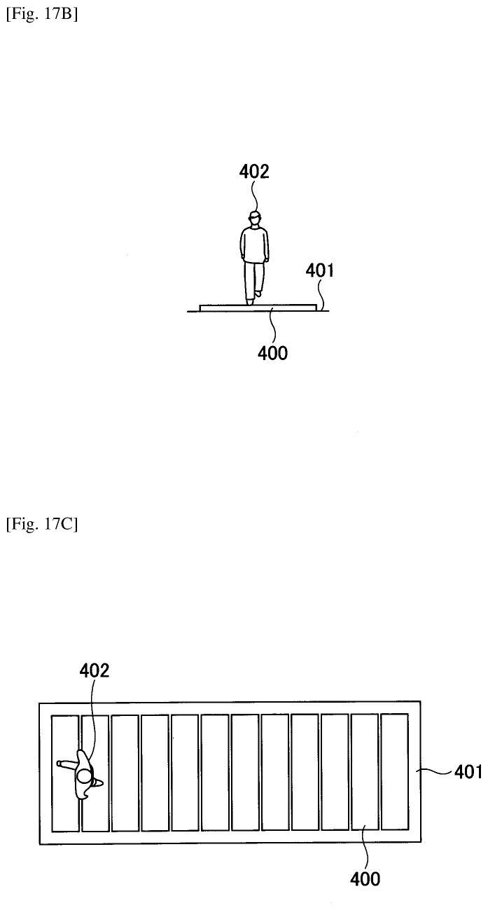

FIGS. 17A to 17C are diagrams illustrating a typical example of detection by the pressure-type passage sensor according to the present embodiment. FIGS. 17A to 17C are diagrams illustrating a person walking along a path, and FIG. 17A is a diagram viewed from the side, FIG. 17B is a diagram viewed from the front (from the direction of movement), and FIG. 17C is a diagram viewed from the top.

As illustrated in FIGS. 17A to 17C, each pressure-type passage sensor 400 is shaped as a strip, and a plurality of the pressure-type passage sensors 400 are arranged to cover the entire floor 401 of the path.

The pressure-type passage sensor 400 detects, by the signal conversion circuits 12a to 12c (see FIGS. 3A to 5B), an output signal based on the pressure applied as a person 402 by walking along the path steps on the pressure-type passage sensor 400, and performs signal processing by the calculating unit 40 (see FIG. 1). From the result of this process, it can be detected that the person 402 is passing (passage can be detected).

The pressure-type passage sensor 400 can also determine the state of passage. For example, the pressure-type passage sensor 400 can determine the number of persons that have passed, whether a particular animal has passed, and whether a particular mobile body has passed. In combination with the photographing results, etc., of a camera provided separately from the pressure-type passage sensor 400, the above-described passage status may be determined. Further, the detection results of the plurality of pressure-type passage sensors 400 can be used to detect the direction of passage of an object such as a person.

By applying a sensor element according to an embodiment to such a pressure-type passage sensor, the same effects as the above-described embodiments can be obtained.

### Seventh Embodiment

Next, a contact state sensor according to the seventh embodiment will be described. Here, the contact state sensor refers to a sensor which detects the contact state of a person or an object based on the pressure applied by a person or an object such as a vehicle.

For example, a contact state sensor may be provided on a chair to detect the contact state, such as whether a person is seated on the chair, whether a person has moved away from the chair, whether a person is leaning on the backrest, or whether a person has moved away from the backrest, etc., by detecting the pressure of the person applied to the chair.

Further, a contact state sensor may be provided on a bed to detect a contact state, such as whether a person is lying on the bed or whether a person has risen from the bed, etc., by detecting the pressure of a person applied onto the bed.

Further, a contact state sensor may be provided on a table mat to detect a contact state, such as whether a cup, such as a coffee cup, is placed on the table mat or whether the cup is lifted, etc. Further, a contact state sensor may be provided on a door knob to detect a contact state, such as whether a person has grasped the door knob or whether a person has released his or her hand from the door knob, etc.

Further, a contact state sensor may be provided on a switch that a person can operate by using his or her finger to switch on or off, to detect the contact state during the operation. A contact state sensor may be provided on the contact portion between a door and a door frame to detect the contact state when opening and closing the door.

Further, the contact state sensor can be used to detect the contact state in the grip section of a robotic arm, or to detect the contact state in each part of the robotic arm to function as a part of a safety device, to detect the contact state with a mobile object such as a vehicle or a drone, or to detect the contact state with a humanoid robot, a glove type sensor, and the like.

<Typical Examples of Contact State Detection by Contact State Sensor>

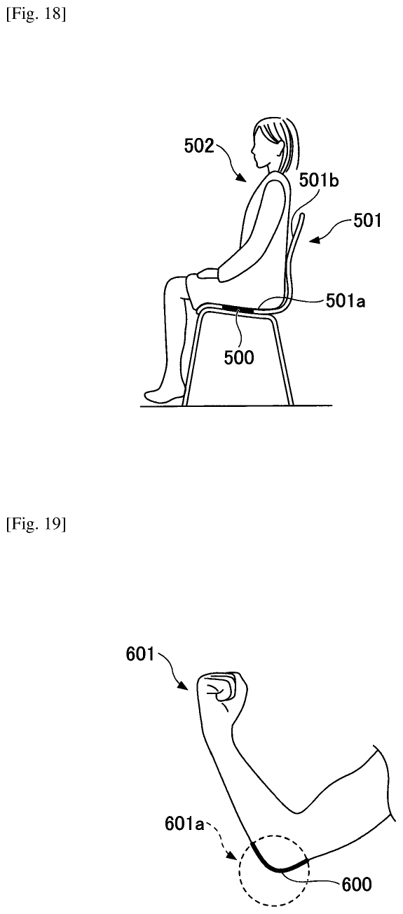

FIG. 18 is a diagram illustrating a typical example of contact state detection by a contact state sensor according to the present embodiment. As illustrated in FIG. 18, a chair 501 includes a seat surface 501a and a backrest 501b, and a contact state sensor 500 is provided on the seat surface 501a. The contact state sensor 500 may be provided on the surface of the seat surface 501a or may embedded within the seat surface 501a.

When a person 502 sits on the chair 501, the contact state sensor 500 detects, by the signal conversion circuit 12c (see FIGS. 5A and 5B), an output signal based on the pressure applied as the person 502 sits on the chair 501, and performs signal processing by the calculating unit 40 (see FIG. 1). By the result of this process, it can be detected that the person 502 has sat on the chair 501.

When the person 502 rises from the chair 501, the contact state sensor 500 detects an output signal based on the reduction in pressure from the person 502 by the signal conversion circuit 12c (see FIGS. 5A and 5B) and performs signal processing by the calculating unit 40 (see FIG. 1). By the result of this process, the separation of the person 502 from the chair 501 can be detected.

By providing the contact state sensor 500 on the backrest 501b, it is possible to detect whether the person 502 has leaned on the backrest 501b.

When the contact state sensor 500 is provided on a switch that a person can operate by using his or her finger to switch on or off, the contact state sensor 500 detects an output signal based on the pressure applied to the switch by the signal conversion circuit 12c (see FIGS. 5A and 5B) and performs signal processing by the calculating unit 40 (see FIG. 1). Thus, it is possible to distinguish between a switch-on operation, a continuous switch-on operation, a switch-off operation, etc., and also to distinguish a long-press operation.

By applying the sensor element according to the embodiment to such a contact state sensor, it is possible to obtain the same effects as the above described embodiments. In the signal conversion circuits 12a and 12b of FIGS. 3A to 4B, the function of contact detection can be obtained, although the detection of a movement is restricted.

### Eighth Embodiment

Next, a bending/stretching sensor according to the eighth embodiment will be described. Here, the bending/stretching sensor refers to a sensor that detects bending/stretching of a person or an object based on the deformation caused by the bending/stretching of a person's joint such as the elbow, shoulder, etc., or the bending/stretching accompanying the opening or the closing of a box or the opening or the closing of a door, etc.

<Typical Example of Bending/Stretching Detection by Bending/Stretching Sensor>

FIG. 19 is a diagram illustrating a typical example of bending/stretching detection by a bending/stretching sensor according to the present embodiment. As illustrated in FIG. 19, a bending/stretching sensor 600 is provided on an elbow 601a of a person 601 and is deformable as the elbow 601a is bent and stretched.

The bending/stretching sensor 600 deforms as the elbow 601a bends and stretches. The bending/stretching sensor 600 detects the output signal based on the deformation by the signal conversion circuit 12c (see FIGS. 5A and 5B) and performs signal processing by the calculating unit 40 (see FIG. 1). By this processing result, it is possible to detect whether the person 601 has bent the elbow 601a, whether the person 601 is maintaining the bending state of the elbow 601a, or whether the person 601 has stretched the elbow 601a, etc.

Based on the detection results of bending/stretching by the bending/stretching sensor 600, it is possible to detect whether a person is walking, running, or doing bending and stretching exercises, and to apply the detection results to rehabilitation or exercise function tests, etc. It is also possible to apply this method to the detection of operations in game machines.

By applying the sensor element according to the embodiment to such a bending/stretching sensor, it is possible to obtain the same effects as in the above-described embodiments.

### Ninth Embodiment

Next, a deformation passage sensor according to the ninth embodiment will be described. Here, the deformation passage sensor refers to a sensor that detects whether a person or an object has passed (detects the passage) based on the deformation caused by a person or an object such as a vehicle.

For example, a deformation passage sensor is provided on an object in the form of a thin sheet, such as a short split curtain (noren, which is a Japanese traditional curtain), and detects the passage of a person or animal based on the deformation of the short split curtain by the motion of passing through the short split curtain. A deformation passage sensor can detect the passage of a person or an object based on the motion of passing through a short split curtain, and also based on the deformation of an object, such as a motion of twisting or pulling the object, etc.

<Typical Example of Passage Detection by Deformation Passage Sensor>

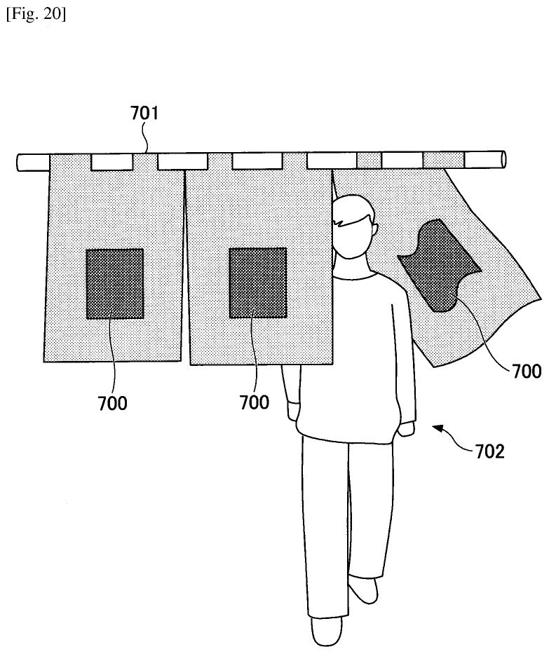

FIG. 20 is a diagram illustrating a typical example of passage detection by a deformation passage sensor according to the present embodiment. As illustrated in FIG. 20, a deformation passage sensor 700 is configured be in the form of a sheet, and three deformation passage sensors 700 are provided at different places in a short split curtain 701. The deformation passage sensor 700 is deformable in accordance with the deformation of the short split curtain 701.

The deformation passage sensor 700 is deformed by the deformation of the short split curtain 701 according to a motion of a person 702 passing through the short split curtain 701. The deformation passage sensor 700 detects an output signal based on the deformation by the signal conversion circuit 12c (see FIGS. 5A and 5B) and performs signal processing by the calculating unit 40 (see FIG. 1). The result of this process can be used to detect the passage of the person 702 through the location (point) where the short split curtain 701 is installed.

The short split curtain 701 is also deformed by an air flow such as wind, and, therefore, the calculating unit 40 preferably determines whether the output signal of the signal conversion circuit 12c is caused by an air flow or by the passage of a person or an animal. The mode of deformation of the short split curtain 701 differs between the case in which a person, etc., passes through the short split curtain 701 and the case in which the short split curtain 701 swings by the flow of air, and, therefore, the characteristic of the waveform of the output signal from the deformation passage sensor 700 also differs depending on the mode of deformation. Therefore, the calculating unit 40 can determine whether the output signal of the signal conversion circuit 12c is caused by the flow of air or the passage of a person or an animal based on the characteristic of the waveform of the output signal from the deformation passage sensor 700.

Further, by a motion such as twisting and pulling, etc., the output signal will have a characteristic waveform, and, therefore, each motion can be identified by processing by the calculating unit 40. This can be applied to detect the motion of a robot in robot control and to detect an operation in a game machine and the like.

While the embodiments of the present invention have been described in detail above, the present invention is not limited to the described embodiments, and various variations and modifications are possible within the scope of the embodiments of the present invention as defined in the appended claims.

Further, by amplifying the signal converter with an active element, it is possible to process a biological signal with the power generation rubber.

The functions of the detecting unit and the calculating unit described above can be implemented by one or more processing circuits. As used herein, a “processing circuit” includes a processor programmed to execute each function by software such as a processor implemented in an electronic circuit; or devices such as an Application Specific Integrated Circuit (ASIC) a digital signal processor (DSP), a field programmable gate array (FPGA), and a conventional circuit module, designed to execute the functions of the detecting unit and the calculating unit.

### REFERENCE SIGNS LIST

1 sensor system
10, 10A, 10B sensor element
11 charge generation rubber (example of charge generation element)
111 first electrode
112 second electrode
113 intermediate layer
12 signal conversion circuit (example of signal converter)
122 output terminal
123 GND terminal
124 VDD terminal
20 power source
21 secondary battery (example of power storage element)
30 detecting unit
40 calculating unit
50 processing unit
51 power storage unit
52 storage unit
53 communication unit
60 power generating unit
70 material portion
80 smartphone
200 insole
300 footwear
400 pressure-type passage sensor
500 contact state sensor
600 bending/stretching sensor
700 deformation passage sensor
S_{A} output signal
S_{AP} peak voltage in positive direction (example of extreme value in positive direction)
S_{AV} peak voltage in negative direction (example of extreme value in negative direction)
S_{AB} reference voltage
S_{EH} signal according to charge
S_{D} digital signal
S_{C} analysis data
VDD1 to VDD7 voltage
R1 to R7 resistor
C1 to C3 capacitor
D1 to D5 diode
W_{range} power usage range
V_{range} voltage change range

The present application is based on and claims priority of Japanese Priority Application No. 2020-010355 filed on Jan. 24, 2020, Japanese Priority Application No. 2020-011863 filed on Jan. 28, 2020, and Japanese Priority Application No. 2020-199114 filed on Nov. 30, 2020, the entire contents of which are hereby incorporated herein by reference.

1. A sensor element used in a sensor system, the sensor system including at least one of a detector and a calculator, and a power source, the sensor element comprising:
a charge generation element configured to generate a charge in response to an external stimulus; and
a signal converter configured to convert the charge into a predetermined output signal, wherein
the signal converter is formed of one or more passive elements only, and an initial driving power for the signal converter is supplied from the power source.

2. The sensor element according to claim 1, wherein the power source is configured to supply power to at least one of the detector and the calculator.

3. The sensor element according to claim 1,
wherein the charge generation element is a piezoelectric element configured to generate the charge according to pressure applied to the piezoelectric element.

4. The sensor element according to claim 1, wherein the predetermined output signal includes extreme values in two directions, including an extreme value in a positive direction and an extreme value in a negative direction.

5. The sensor element according to claim 1, wherein a power supply source of the signal converter and a power supply source of at least one of the detector and the calculator are the same power source.

6. The sensor system comprising:
the sensor element according to claim 1; and
the detector configured to detect the predetermined output signal of the sensor element.

7. The sensor system comprising:
the sensor element according to claim 1; and
the calculator configured to analyze the predetermined output signal of the sensor element.

8. The sensor system according to claim 6, wherein the power source includes a power storage element configured to store power.

9. The sensor system according to claim 8, wherein the power storage element is a secondary battery.

10. The sensor system according to claim 9, wherein a range of the power of the secondary battery used by the signal converter is defined to be a predetermined range based on a voltage value output from the secondary battery to the signal converter.

11. The sensor system according to claim 9, wherein a range of the power of the secondary battery used by at least one of the detector and the calculator is defined to be a predetermined range based on a voltage value output from the secondary battery to at least one of the detector and the calculator.

12. The sensor system according to claim 10, wherein the predetermined range is greater than or equal to 10 percent and less than or equal to 90 percent.
